(19) United States
(12) Patent Application Publication
(10) Pub. No.: US 2026/0148374 A1
(43) Pub. Date: May 28, 2026

(54) EVALUATION METHOD, EVALUATION APPARATUS, AND COMPUTER PROGRAM

(71) Applicant: Tokyo Electron Limited, Tokyo (JP)

(72) Inventor: Taisei KONDO, Sapporo City (JP)

(73) Assignee: Tokyo Electron Limited, Tokyo (JP)

(21) Appl. No.: 19/450,734

(22) Filed: Jan. 16, 2026

Related U.S. Application Data
(63) Continuation of application No. PCT/JP2024/025929, filed on Jul. 19, 2024.

(30) Foreign Application Priority Data
Jul. 27, 2023 (JP) 2023-122651

(51) Int. Cl. G06T 7/00; G06V 10/26; G06V 10/32; G06V 10/40; G06V 10/74; H10P 72/00; H10P 74/20

(52) U.S. Cl. CPC G06T 7/001; G06V 10/273; G06V 10/32; G06V 10/40; G06V 10/761; G06T 2207/10061; G06T 2207/20081; G06T 2207/30121; G06T 2207/30148; G06V 2201/06; H10P 72/0616; H10P 74/203

(57) ABSTRACT

An evaluation method, an evaluation apparatus, and a computer program are provided. The evaluation method includes acquiring a surface image of a material as an evaluation target; extracting a first feature from the surface image; reading, from a memory, a plurality of second features extracted from surface images of a plurality of materials having structural uniformity; calculating a distance in a feature space between the first feature and a second feature of the plurality of second features; calculating, based on the distance, an evaluation value for quantitatively evaluating a structural uniformity of the material as the evaluation target; and outputting the evaluation value.

### CROSS-REFERENCE TO RELATED APPLICATIONS

This application is a bypass continuation application of international application No. PCT/JP 2024/025929 having an international filing date of Jul. 19, 2024 and designating the United States, the international application being based upon and claiming the benefit of priority from Japanese Patent Application No. 2023-122651, filed on Jul. 27, 2023, the entire contents of each are incorporated herein by reference.

### TECHNICAL FIELD

The present invention relates to an evaluation method, an evaluation apparatus, and a computer program.

### BACKGROUND

In the related art, a visual test of substrates is performed in various processing steps of substrate processing (see, for example, PTL 1). In the visual test, for example, an operator visually checks a surface image obtained by imaging of a surface of a substrate as a test object to determine whether a process is good or bad.

### CITATION LIST

### Patent Documents

PTL 1: JP2018-197696A

### SUMMARY

An evaluation method according to the present disclosure includes acquiring a surface image of a material as an evaluation target; extracting a first feature from the surface image; reading, from a memory, a plurality of second features extracted from surface images of a plurality of materials having structural uniformity; calculating a distance in a feature space between the first feature and a second feature of the plurality of second features; calculating, based on the distance, an evaluation value for quantitatively evaluating a structural uniformity of the material as the evaluation target; and outputting the evaluation value.

### BRIEF DESCRIPTION OF DRAWINGS

FIG. 1 is a diagram illustrating a configuration of an evaluation system according to an embodiment.

FIGS. 2A and 2B are schematic diagrams illustrating a structure of a substrate as an evaluation target.

FIGS. 3A and 3B are schematic diagrams illustrating an example of a structure of a substrate having deteriorated structural uniformity.

FIG. 4 is a diagram illustrating a main component configuration of a learning model.

FIG. 5 is a block diagram illustrating an internal configuration of an evaluation apparatus.

FIG. 6 is a flowchart illustrating an extraction procedure when features are extracted from a substrate as a non-defective product.

FIG. 7 is a flowchart illustrating an evaluation procedure when evaluating the substrate as an evaluation target.

FIGS. 8A and 8B are schematic diagrams illustrating a display example of evaluation values and evaluation images.

FIG. 9 is a schematic view illustrating another display example of the evaluation image.

FIG. 10 is a conceptual diagram illustrating an example of a table in which parameters included in a process recipe and evaluation values are stored in association with each other.

FIGS. 11A and 11B are graphs illustrating correlations between the parameters included in the process recipe and the evaluation values.

FIG. 12 is a flowchart illustrating a procedure for optimizing the process recipe.

### DETAILED DESCRIPTION

The present disclosure provides an evaluation method, an evaluation apparatus, and a computer program capable of performing quantitative evaluation regardless of a skill of an operator.

Hereinafter, an embodiment will be described with reference to the drawings. In the description, the same elements or elements having the same function are denoted by the same reference numerals, and overlapping descriptions thereof will be omitted.

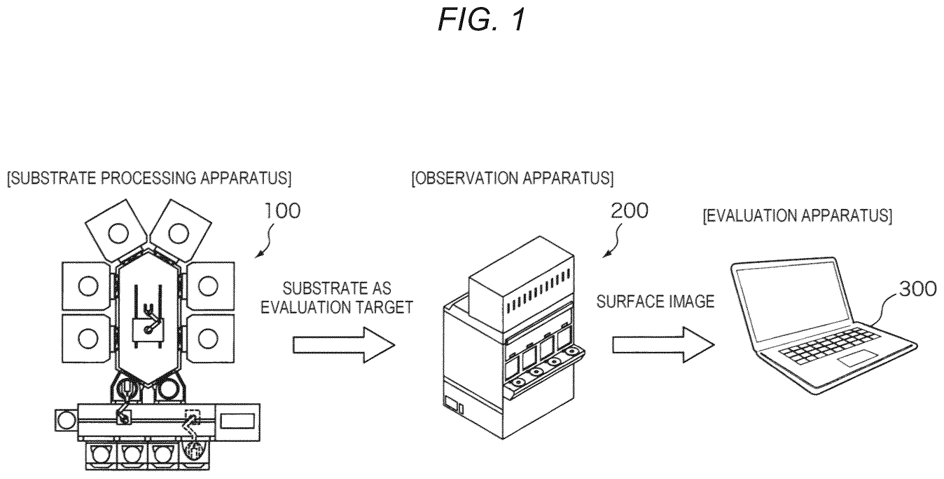

FIG. 1 is a diagram illustrating a configuration of an evaluation system according to an embodiment. The evaluation system according to the embodiment includes a substrate processing apparatus 100, an observation apparatus 200, and an evaluation apparatus 300.

The substrate processing apparatus 100 is an apparatus for performing processing on a substrate (wafer). For example, the substrate processing apparatus 100 is a semiconductor manufacturing apparatus of an exposure apparatus, an etching apparatus, a film forming apparatus, an ion implantation apparatus, an ashing apparatus, a sputtering apparatus, and the like. Alternatively, the substrate processing apparatus 100 may be a display manufacturing apparatus that manufactures a flat display panel (FDP) such as a liquid crystal display panel or an organic electro-luminescence (EL) panel.

When the substrate is processed in the substrate processing apparatus 100, various setting values for a temperature of a substrate, a pressure or a gas flow rate in a chamber, a voltage applied from a radio-frequency power supply, and the like are set. The setting value is given by, for example, a process recipe. Further, the substrate processing apparatus 100 is provided with various sensors and devices that measure the temperature of the substrate, the pressure and gas flow rate in the chamber, voltages applied to an upper electrode and a lower electrode, a plasma emission intensity, and the like, and various measurement values are measured during execution of the process. The substrate processing apparatus 100 collects appropriate time series data such as images of the substrate before and after the process and process logs at any time in addition to the measurement values described above.

The observation apparatus 200 is an apparatus that observes a surface of the substrate processed by the substrate processing apparatus 100. The observation apparatus 200 is, for example, a scanning electron microscope (SEM). In the scanning electron microscope, a surface of a sample is irradiated with an electron beam, and electrons (especially secondary electrons) scattered on the surface of the sample are detected. The scanning electron microscope measures an amount of the secondary electrons while performing scanning with the electron beam, thereby generating an image that reflects a surface structure of the sample. The observation apparatus 200 observes the surface of the substrate using such a scanning electron microscope, and generates an image (hereinafter referred to as a surface image) that reflects the surface structure of the substrate. The observation apparatus 200 outputs the generated surface image to the evaluation apparatus 300.

In the embodiment, the observation apparatus 200 is a scanning electron microscope. Alternatively, the observation apparatus 200 may be an observation apparatus such as a transmission electron microscope (TEM) or a scanning acoustic microscope (SAM). Further, the observation apparatus 200 may be an observation apparatus mounted on the substrate processing apparatus 100, which observes the surface of the substrate during the process, and outputs the obtained surface image to the evaluation apparatus 300.

The evaluation apparatus 300 is a computer that quantitatively evaluates structural uniformity of the substrate based on the surface image received from the observation apparatus 200. In the embodiment, the structural uniformity represents uniformity of the structure formed on the surface of the substrate. For example, when a substrate on which a hole pattern is formed is an evaluation target, the evaluation apparatus 300 may evaluate uniformity on an arrangement of holes or uniformity on shapes of holes as the structural uniformity. Although an evaluation method will be described in detail later, the evaluation apparatus 300 according to the present embodiment compares features extracted from the surface image of the substrate that is regarded as a non-defective product with features extracted from the surface image of the substrate that is the evaluation target, thereby calculating an evaluation value for quantitatively evaluating the structural uniformity, and outputting the calculated evaluation value.

In the present embodiment, the substrate processed in the substrate processing apparatus 100 will be described as the evaluation target. However, the evaluation target is not limited to the substrate processed in the substrate processing apparatus 100, and may be any material.

In the present embodiment, the substrate processing apparatus 100, the observation apparatus 200, and the evaluation apparatus 300 are described as separate apparatuses. Alternatively, the evaluation apparatus 300 may be provided inside the substrate processing apparatus 100 or may be provided inside the observation apparatus 200.

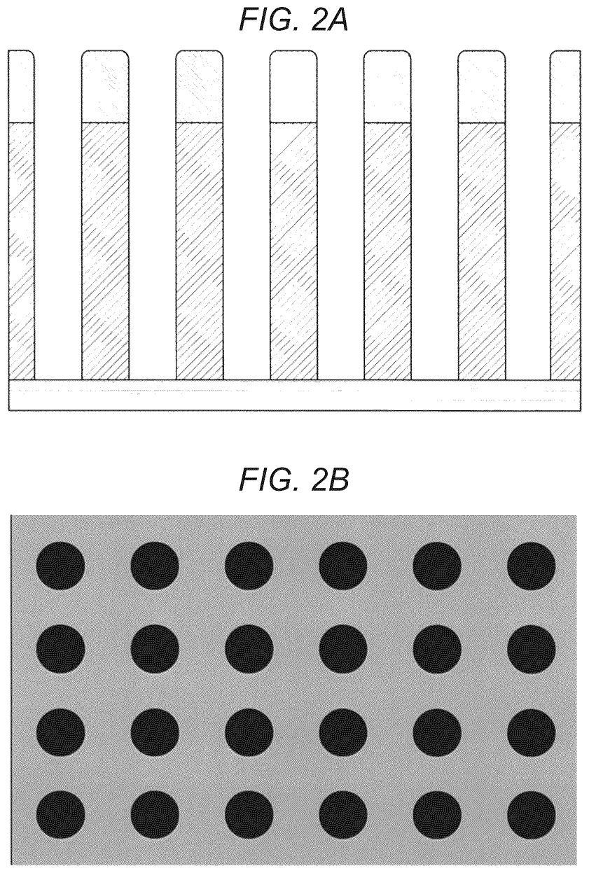

Hereinafter, a substrate on which a hole pattern is formed will be described as an example of the substrate as the evaluation target. FIGS. 2A and 2B are schematic diagrams illustrating the structure of the substrate as the evaluation target. FIG. 2A is a side cross-sectional view of the substrate on which the hole pattern is formed. For example, a dry etching technique is used for forming the hole pattern. In the dry etching, a plurality of reactive gases are introduced into a reaction chamber, the reactive gases are excited, dissociated, and ionized by plasma, and various particle species (radicals and ions) generated at that time are emitted onto the substrate. Since the ions enter the surface of the substrate in a vertical direction to cause a reaction, it is possible to perform processing with high anisotropy, and by protecting a part of a film with an appropriate mask material, the hole pattern reflecting a mask shape can be formed.

FIG. 2B schematically illustrates a surface image obtained from the observation apparatus 200. When the substrate on which the hole pattern is formed is observed using the scanning electron microscope (observation apparatus 200), a quantity of electrons detected by a detector of the scanning electron microscope differs between a region where a hole is formed and a region where no hole is formed, and thus the quantity of electrons appears as a grayscale of the image. For example, since there is a property (edge effect) in which many secondary electrons are scattered from a sheer location having a large angle, and fewer secondary electrons are scattered from a flat location, when a grayscale image is generated such that a region where a quantity of detected secondary electrons is larger becomes darker, an image in which a grayscale value of a region corresponding to a hole is low and a grayscale value of the region other than the region corresponding to a hole becomes higher (that is, an image in which the region corresponding to a hole is darker than the surroundings) is obtained, as illustrated in FIG. 2B.

FIG. 2B illustrates an example of a surface image when the hole patterns are uniformly formed. When the hole patterns are uniformly formed, the grayscale value is low only in the region corresponding to the hole, and the grayscale values of the other regions do not decrease. Further, when the hole has a shape close to a perfect circle, the region in which the grayscale value is low becomes a shape close to a perfect circle reflecting the shape of the hole.

In contrast to the example illustrated in FIG. 2B, in an actual etching technique, various shape abnormalities may occur. For example, pattern defects may probabilistically occur on the surface of the substrate due to fluctuations in a number of photons during exposure, non-uniformity of resist constituent materials, deterioration of contrast of an exposure apparatus, and the like. Since a flux of radicals may be high from the surface of the substrate to a sidewall of an upper portion of a mask, a deposited film is likely to be generated. Further, a sidewall portion is resistant to irradiation of ions, and thus an overhanging shape (referred to as necking) is generated. When an opening diameter of the hole is reduced by the necking, a re-sputtered substance adheres to a surface facing the sidewall portion, and clogging in which the hole is clogged is likely to occur. In a middle portion of the hole, enlarging of a hole diameter referred to as bowing is likely to occur. A vertical stripe-shaped shape abnormality (referred to as striation) may occur in the sidewall of the hole. Further, a phenomenon (tilting) in which a hole that is supposed to be formed perpendicularly is obliquely formed or a phenomenon (twisting or bending) in which a direction of a hole is bent at a bottom may occur. Further, the hole diameter gradually decreases in a cross-sectional direction of the substrate, and a taper may be formed.

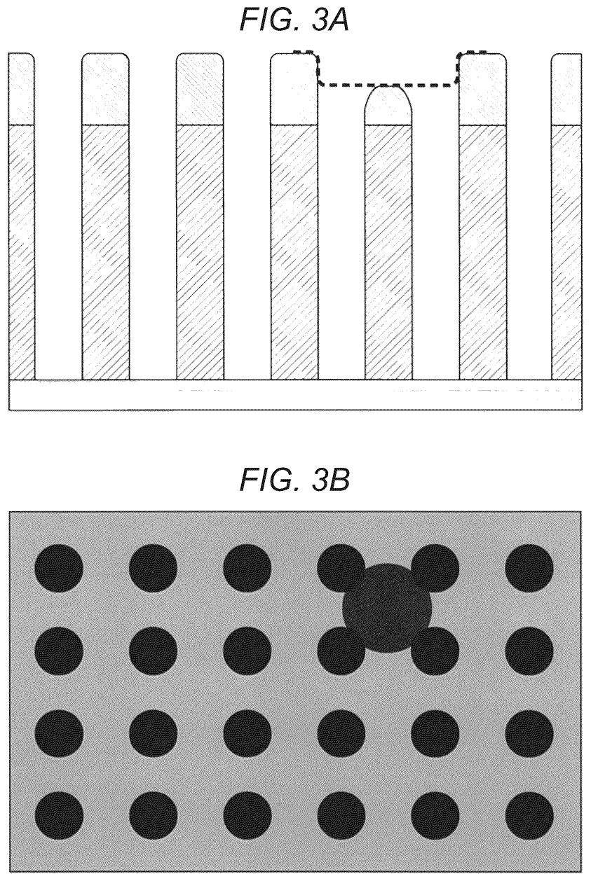

When such a shape abnormality occurs, the structural uniformity of the substrate deteriorates. FIGS. 3A and 3B are schematic diagrams illustrating an example of a structure of a substrate having deteriorated structural uniformity. FIG. 3A illustrates an example in which a fine step (pattern defect) occurs on a part of the surface of the substrate. That is, in FIG. 3A, a step is generated in a portion indicated by a broken line. Such a step is probabilistically formed due to, for example, the fluctuations in the number of photons during exposure, the non-uniformity of the resist constituent material, and the deterioration of the contrast of the exposure apparatus. When the substrate having a step formed on the surface is observed with the scanning electron microscope (observation apparatus 200), a surface image as illustrated in, for example, FIG. 3B is obtained. Since the hole pattern is formed in the substrate, the grayscale value of the region corresponding to the hole is low as in the example in FIGS. 2A and 2B. In addition, a grayscale value of a region in which the step is formed may also be low. In FIG. 3B, the region in which the step occurs is represented by a circle, and the grayscale value in the region is set to be constant. However, in reality, a shape of the region corresponding to the pattern defect becomes complex and the grayscale value in the region changes in various manners, reflecting the shape of the pattern defect.

Although FIGS. 3A and 3B illustrate an example in which the step is formed in the substrate, in addition to the step, when a shape abnormality such as necking, clogging, bowing, striation, tilting, twisting, bending, or tapering occurs in the substrate, the grayscale reflecting the shape abnormality appears in the surface image (SEM image). Due to such a shape abnormality, the shape of each hole may collapse from the perfect circle, and uniformity of the pattern may deteriorate.

In a visual test according to related art, an operator visually checks the surface image of the substrate to determine whether the process is good or bad. And, whether the process is good or bad is determined based on a subjective view of the operator, and quantitative evaluation is not performed. Further, since the operator visually checks the surface image of the substrate, a fine shape abnormality may be missed.

To address this subjective problem, in the present embodiment, the features are extracted from the surface images obtained for non-defective products (substrates having structural uniformity), and the structural uniformity of the substrate is quantitatively evaluated by comparing with the features extracted from the surface images of the substrate as a test object.

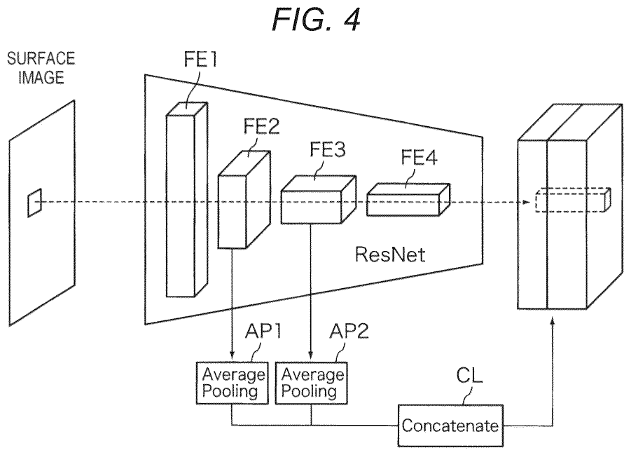

In the present embodiment, a learning model that is trained is used to extract features from a surface image. FIG. 4 is a diagram illustrating a main component configuration of a learning model MD. The learning model MD illustrated in FIG. 4 is a learning model based on a residual neural network (ResNet), and includes a plurality of intermediate layers. An example in FIG. 4 illustrates a configuration in which four feature extraction layers FE1 to FE4 are included as the intermediate layers. Outputs are extracted from a second feature extraction layer L2 and a third feature extraction layer L3 among the four feature extraction layers FE1 to FE4 provided in the learning model MD, and vertical and horizontal dimensions of the outputs are aligned in average pooling layers AP1 and AP2, and then the outputs are coupled in a channel direction by a coupling layer CL, thereby features (feature vectors) are extracted from one surface image. In the example in FIG. 4, the features are generated by the number of patch images obtained by dividing the surface image (=the number of vertical divisions x the number of horizontal divisions of the image). By extracting the features by such a method, the features holding positional information in the image can be obtained.

Although FIG. 4 illustrates the learning model MD based on the ResNet, a model structure of the learning model MD is not limited to the one illustrated in FIG. 4, and any model structure including a general convolutional neural network (CNN) structure can be adopted. For example, the learning model MD may have a model structure used by DN2 (Deep Nearest Neighbor Anomaly Detection), SPADE (Sub-Image Anomaly Detection with Deep Pyramid Correspondences), PaDiM (A Patch Distribution Modeling Framework for Anomaly Detection and Localization), PatchCore (Towards Total Recall in Industrial Anomaly), or the like.

In the present embodiment, the outputs are extracted from the second feature extraction layer L2 and the third feature extraction layer L3 among the four feature extraction layers FE1 to FE4 provided in the learning model MD to extract the features. Therefore, the outputs of the learning model MD itself does not necessarily need to be the features, and may be any probability value or the like calculated based on the features.

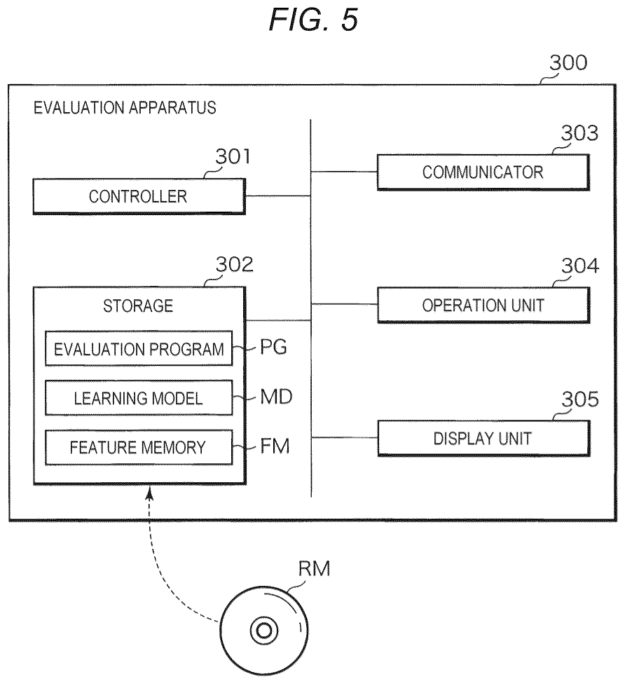

Hereinafter, a configuration of the evaluation apparatus 300 for evaluating a surface image using the learning model MD will be described. FIG. 5 is a block diagram illustrating an internal configuration of the evaluation apparatus 300. The evaluation apparatus 300 is, for example, a dedicated or general-purpose computer including a controller 301, a storage 302, a communicator 303, an operation unit 304, and a display unit 305.

The controller 301 includes a central processing unit (CPU), a read only memory (ROM), a random access memory (RAM), and the like. The ROM provided in the controller 301 stores control programs and the like for controlling operations of components of the hardware provided in the evaluation apparatus 300. The CPU in the controller 301 reads and executes the control programs stored in the ROM and computer programs stored in the storage 302 to be described later, and controls the operations of the components of the hardware, and thus causes the entire apparatus to function as the evaluation apparatus according to the present disclosure. The RAM provided in the controller 301 temporarily stores data used during the execution of an arithmetic operation.

In the embodiment, although the controller 301 includes the CPU, the ROM, and the RAM, the configuration of the controller 301 is not limited to the above-described configuration. The controller 301 may be, for example, one or a plurality of control circuits or arithmetic circuits that include a graphics processing unit (GPU), a field programmable gate array (FPGA), a digital signal processor (DSP), a quantum processor, a volatile or nonvolatile memory, or the like. In addition, the controller 301 may include functions such as a clock for outputting date and time information, a timer for measuring a time elapsed from the time when a measurement start instruction is applied to the time when a measurement end instruction is applied, and a counter for counting the number.

The storage 302 includes storage devices such as a hard disk drive (HDD), a solid state drive (SSD), and an electronically erasable programmable read only memory (EEPROM). The storage 302 stores various types of computer programs executed by the controller 301 and various data used by the controller 301.

The computer program (program product) stored in the storage 302 includes an evaluation program PG that causes the computer to execute, based on a surface image of a substrate as an evaluation target, a process of deriving an evaluation value for quantitatively evaluating processing accuracy uniformity, and outputting the derived evaluation value. The evaluation program PG may be a single computer program or may be a program group including a plurality of computer programs. The evaluation program PG may be executed by a plurality of computers in cooperation with each other. In addition, the evaluation program PG may partially use an existing library.

The computer program that includes the evaluation program PG is provided by a non-temporary recording medium RM on which the computer program is recorded in a readable manner. The recording medium RM is a portable memory such as a CD-ROM, a USB memory, a secure digital (SD) card, a micro SD card, or a compact flash (registered trademark). The controller 301 reads various types of computer programs from the recording medium RM using a reading device and stores the read various types of computer programs in the storage 302. The computer program that includes the evaluation program PG may be provided through communication. In this case, the controller 301 acquires a computer program that includes the evaluation program PG through communication via the communicator 303, and causes the storage 302 to store the acquired computer program.

The storage 302 stores the above-described learning model MD. In the present embodiment, the learning model MD that is trained is stored in the storage 302. The learning model MD can be trained using a known method, and the description thereof will be omitted in the present embodiment.

In the present embodiment, the evaluation apparatus 300 includes the learning model MD. Alternatively, the learning model MD may be stored in an external apparatus. In this case, the controller 301 of the evaluation apparatus 300 may access the external apparatus via a communication network, transmit the surface image acquired from the observation apparatus 200 to the external apparatus, and acquire an evaluation value obtained as a result of an arithmetic operation by the external apparatus via the communication network.

The storage 302 includes a feature memory FM that stores features extracted from a surface image of a substrate regarded as a non-defective product. The features of the non-defective product are collected in a learning phase before a start of an actual operation (evaluation of substrates), and stored in advance in the feature memory FM. The feature memory FM does not need to be hardware, and may be any storage area formed in the storage 302. Further, the feature memory FM may be provided inside the evaluation apparatus 300 or may be provided outside the evaluation apparatus 300.

The communicator 303 includes a communication interface, such as a transceiver or transmission and reception circuit, for transmitting and receiving various types of data to and from an external apparatus. As the communication interface of the communicator 303, a communication interface conforming to a communication standard such as a local area network (LAN) can be used. The external apparatus includes the substrate processing apparatus 100, the observation apparatus 200, and a user terminal. When data to be transmitted is received from the controller 301, the communicator 303 transmits the data to the external apparatus that is a destination, and outputs the received data to the controller 301 when the data transmitted from the external apparatus is received.

The operation unit 304 includes operating devices such as a touch panel, a keyboard, and switches, and receives various types of operations and settings by the user or the like. The controller 301 performs appropriate controls based on various types of operation information supplied by the operation unit 304, and causes the storage 302 to store setting information as needed.

The display unit 305 includes a display device such as a liquid crystal monitor or an organic electro-luminescence (EL) monitor, and displays information to be notified to the user or the like in response to an instruction from the controller 301.

In the present embodiment, the evaluation apparatus 300 may be a single computer or may be a computer system including a plurality of computers, peripheral devices, and the like. In addition, the evaluation apparatus 300 may be a virtual machine in which entities are virtualized, or may be a cloud.

Hereinafter, the operation of the evaluation apparatus 300 will be described.

The evaluation apparatus 300 according to the present embodiment extracts features for the non-defective product in the learning phase before the actual operation is started. The storage 302 of the evaluation apparatus 300 stores the learning model MD that is trained.

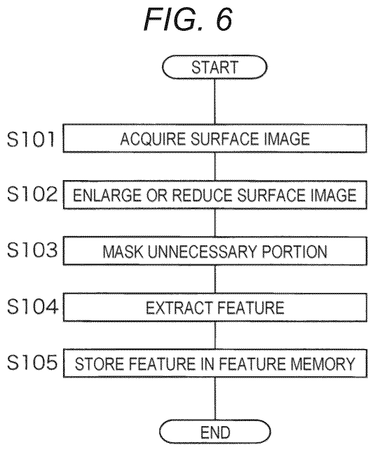

FIG. 6 is a flowchart illustrating an extraction procedure when features are extracted from a substrate as a non-defective product. The controller 301 of the evaluation apparatus 300 acquires a surface image of a substrate that is regarded as a non-defective product through the communicator 303 (step S101). Here, the operator checks the surface image of the substrate, and acquires a plurality of surface images (hereinafter, also referred to as non-defective images) determined to be a non-defective product. The operator may determine the non-defective product by paying attention to the uniformity of the pattern, or may determine the non-defective product by paying attention to the shape (roundness) of each hole. Further, the operator may determine the non-defective product by paying attention to a surface state accompanying cleaning of the substrate, or may determine the non-defective product by paying attention to a degree of deterioration of the surface accompanying the substrate processing.

The controller 301 performs pre-processing on the acquired surface image. Specifically, the controller 301 enlarges or reduces each surface image such that imaging magnifications of the plurality of acquired surface images are the same (step S102). In addition, the controller 301 masks unnecessary or extra portions in the surface image (step S103). The controller 301 may execute the processing in steps S102 and S103 as needed. For example, when the surface image with the same imaging magnification is obtained in the observation apparatus 200, the processing in step S102 may be omitted. Further, when only the structure as the evaluation target (for example, the hole pattern) is included in the surface image and no other extra structure is included, the processing in step S103 may be omitted.

The controller 301 inputs the surface image subjected to the pre-processing into the learning model MD, and extracts features (step S104). For example, in a progress of executing an arithmetic operation using the learning model MD, the controller 301 extracts outputs from the intermediate layers (the feature extraction layers FE2 and FE3), and extracts features by combining the extracted outputs in a channel direction with the dimensions aligned. The feature is represented by a feature vector (or feature tensor).

The controller 301 causes the feature memory FM to store the features extracted in step S104 (step S105). The controller 301 may cause the feature memory FM to selectively store features representative of non-defective images among the features extracted in step S104. The controller 301 executes the processing in steps S102 to S105 for each of the plurality of surface images acquired in step S101, and causes the feature memory FM to store the extracted features.

Through the above procedure, the feature memory FM stores a plurality of features extracted from the surface image of the substrate that is regarded as a non-defective product.

The evaluation apparatus 300 performs quantitative evaluation on the substrate as the evaluation target in an actual operation phase after the learning phase is completed.

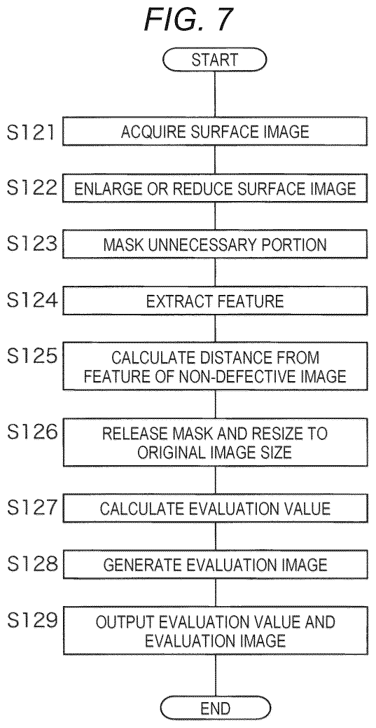

FIG. 7 is a flowchart illustrating an evaluation procedure when evaluating a substrate as the evaluation target. The controller 301 of the evaluation apparatus 300 acquires a surface image of a substrate as the evaluation target through the communicator 303 (step S121). The substrate as the evaluation target is a substrate processed by the substrate processing apparatus 100 (for example, a substrate on which a hole pattern is formed). The surface image is an image obtained by observing a substrate processed by the substrate processing apparatus 100 with the observation apparatus 200.

The controller 301 performs pre-processing on the acquired surface image. Specifically, the controller 301 enlarges or reduces each surface image such that imaging magnifications of the plurality of acquired surface images are the same (step S122). In addition, the controller 301 masks unnecessary or extra portions in the surface image (step S123). These pieces of processing are similar to the processing in steps S102 and S103 performed on the non-defective image.

The controller 301 inputs the surface image subjected to the pre-processing into the learning model MD, and extracts features (step S124). For example, in a progress of executing an arithmetic operation using the learning model MD, the controller 301 extracts outputs from the intermediate layers (the feature extraction layers FE2 and FE3), and extracts features by combining the extracted outputs in a channel direction with the dimensions aligned. By using the learning model MD, the controller 301 can extract features as many as the number of patch images obtained by dividing a surface image.

The controller 301 reads the features (features of non-defective images) stored in the feature memory FM, and calculates a distance between the features extracted in step S124 and the features read from the feature memory FM (step S125). For example, the controller 301 maps the features extracted in step S124 and the features read from the feature memory FM into a feature space, and calculates the distance between the features in the mapped feature space. Features (features holding positional information) for each of the plurality of divided patch images are obtained from one surface image. The controller 301 calculates the distance between each feature extracted from the patch image and the feature read from the feature memory FM. The distance calculated in step S125 may be any scale representing similarity/dissimilarity between features, and may be, for example, a Euclidean distance or a Mahalanobis distance.

The controller 301 releases the mask applied to the surface image and resizes the surface image to an original image size (step S126). That is, the controller 301 executes the reverse procedure to steps S122 and S123.

Based on the distance calculated in step S125, the controller 301 calculates an evaluation value that quantitatively evaluates the structural uniformity of the substrate as the evaluation target (step S127). In step S125, the controller 301 calculates the distance between the feature of each patch image and the feature of the non-defective image. The controller 301 calculates, for example, an average value, a variance, a minimum value, and a maximum value of the calculated distance as evaluation values (evaluation values for one surface image). Alternatively, the controller 301 may adopt the distance calculated for each patch image as the evaluation value (evaluation value holding positional information). Further, the controller 301 may calculate a reciprocal of the average value, the variance, the minimum value, and the maximum value of the calculated distance as the evaluation value, or may calculate the evaluation value by using a function using these values as variables.

Based on the distance calculated in step S125, the controller 301 generates an evaluation image indicating the evaluation of the structural uniformity for the substrate as the evaluation target (step S128). The controller 301 generates an evaluation image based on a length of the distance calculated for each patch image. When the calculated distance is relatively short, the relatively short distance indicates that the similarity with the non-defective image is high and the structure uniformity is high, and conversely, when the calculated distance is relatively long, the relatively long distance indicates that the similarity with the non-defective image is low and the structure uniformity is low. Therefore, the controller 301 generates, as an evaluation image, a grayscale image or a heat map obtained by setting a grayscale or color of an image, based on the length of the distance calculated for each patch image.

When a non-defective image having high uniformity of the pattern is selected during the training based on the non-defective image, and a feature is extracted from the selected non-defective image to construct the feature memory FM, an evaluation image reflecting the uniformity of the pattern is obtained in step S128. Meanwhile, when a non-defective image in which the shape of each hole is close to the perfect circle is selected during the training using the non-defective image, and the feature is extracted from the selected non-defective image to construct the feature memory FM, an evaluation image reflecting the roundness of the shape of the hole is obtained in step S128.

The reliability may be improved by comparing the evaluation value obtained by evaluation using this method with the evaluation value of roundness derived by using another method such as contour extraction, and performing selection of the features stored in the feature memory FM according to the comparison result.

The evaluation value and the evaluation image related to the uniformity of the pattern and the evaluation value and the evaluation image related to the roundness may be presented to the operator, and the evaluation value and the evaluation image to be fed back to the process recipe may be selected by the operator.

In a case of constructing the feature memory FM by observing the surface state after the substrate cleaning, selecting a non-defective image having a good surface state, and extracting the feature from the selected non-defective image when the training using the non-defective image is performed, in step S128, an evaluation image reflecting the surface state of the substrate is obtained. Further, in the case of constructing the feature memory FM by observing the surface state after the substrate processing, selecting a non-defective image having small deterioration in the surface, and extracting the feature from the selected non-defective image when the training using the non-defective image is performed, in step S128, an evaluation image reflecting the degree of deterioration of the substrate surface is obtained.

The controller 301 outputs the evaluation value calculated in step S127 and the evaluation image generated in step S128 (step S129). The controller 301 displays the calculated evaluation value and the generated evaluation image on the display unit 305, thereby outputting the evaluation value and the evaluation image. Alternatively, the controller 301 may notify the terminal device of the user of the calculated evaluation value and the generated evaluation image through the communicator 303.

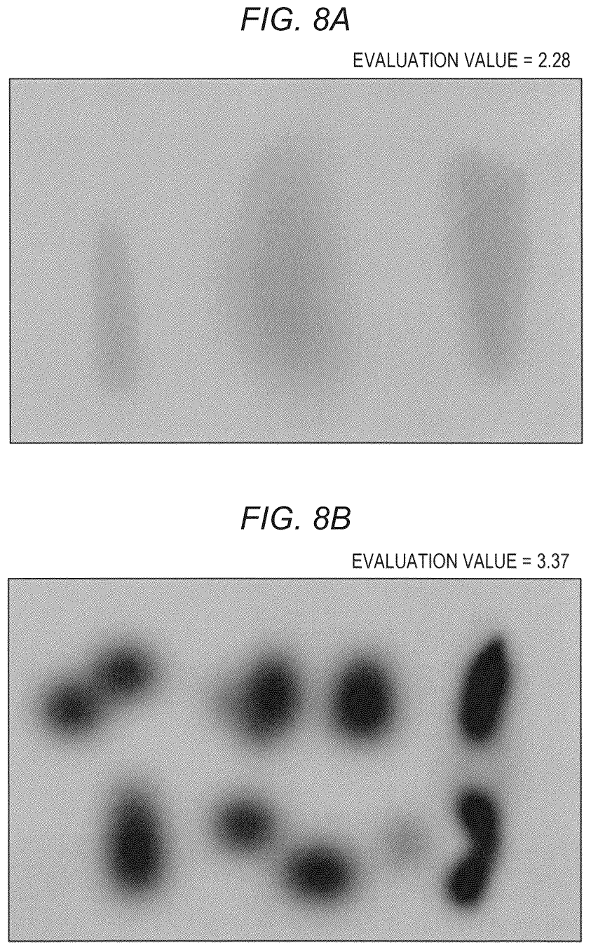

FIGS. 8A and 8B are schematic diagrams illustrating a display example of evaluation values and evaluation images. FIGS. 8A and 8B illustrate an example of an evaluation image in which the maximum value of the distance calculated in one surface image is adopted as the evaluation value, and the evaluation image is shaded such that the longer the distance calculated in the surface image, the darker the region. FIG. 8A illustrates an example in which an evaluation image having a small evaluation value and less unevenness in grayscale is obtained, and the structural uniformity is high. On the other hand, FIG. 8B illustrates an example in which an evaluation image having a large evaluation value and large unevenness in grayscale is obtained, and the structural uniformity is low. The operator can determine whether the process performed when the substrate is processed by the substrate processing apparatus 100 is good or bad by referencing the evaluation values and the evaluation images displayed on the display unit 305. The evaluation image is not limited to a grayscale image, and may be a heat map in which colors differ according to evaluation values, or may be a contour map using contours.

The controller 301 may superimpose and display the evaluation image on the surface image. Specifically, the controller 301 may transparently display an evaluation image by the grayscale or the like, and superimpose the evaluation image on the surface image of the substrate as a test object. Further, the controller 301 may display the evaluation value in the image. The evaluation value may be an evaluation value for each set area, or may be an average of the evaluation values for each area.

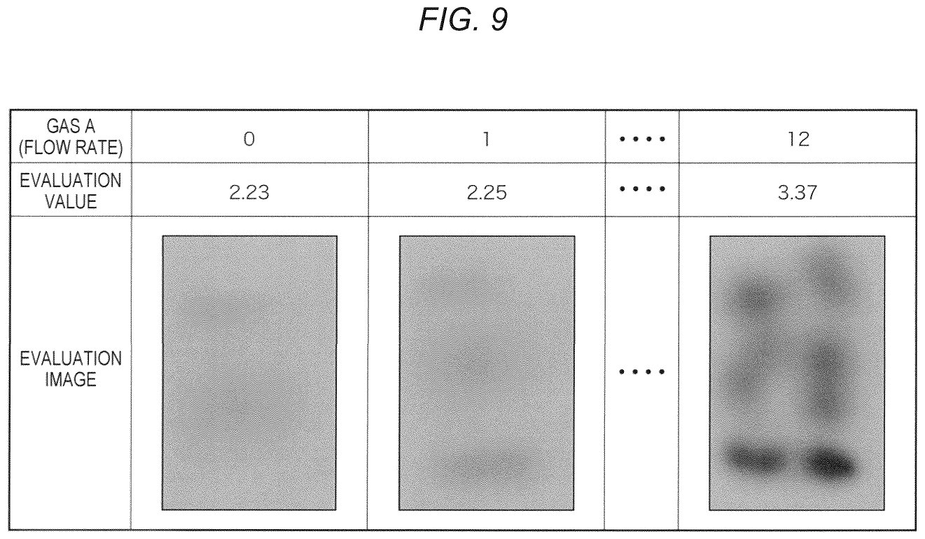

The controller 301 may generate the evaluation image for each process recipe, and control display unit 305 to display the evaluation images in a descending order of evaluation values. Such is shown in FIG. 9, which illustrates is a schematic view of another display example of the evaluation images. In particular, FIG. 9 illustrates an example in which evaluation images are displayed in a list from left to right in descending order of the evaluation values.

As described above, the structural uniformity of the substrate can be quantitatively evaluated by comparing the features extracted from the surface image of the substrate as a test object with the features extracted from the surface image of a non-defective product (substrate having structural uniformity).

In the present embodiment, a user may select uniform data (surface image), and a quality of annotation is improved as compared with a conventional regression analysis and classification processing.

Moreover, since the evaluation value is calculated by comparing the features, the evaluation value can also be applied to the evaluation target in which the quantified value is not present.

In another embodiment, a configuration will be described in which correlations between parameters included in a recipe used when a substrate is processed and evaluation values calculated based on a surface image are calculated, and the recipe is optimized based on the calculated correlations.

Since the overall configuration of the evaluation system, the internal configuration of the evaluation apparatus 300, and the like are the same as those discussed above, the description thereof will be omitted.

The evaluation apparatus 300 according to this embodiment acquires a plurality of types of recipes (process recipes) used when substrates are processed by the substrate processing apparatus 100, and stores, in the storage 302, the parameters included in each process recipe and the evaluation values calculated based on the surface images in association with each other.

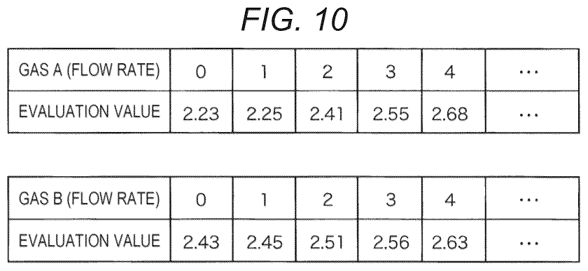

FIG. 10 is a conceptual diagram illustrating an example of a table in which a parameter included in a process recipe and evaluation values are stored in association with each other. The example in FIG. 10 illustrates a relationship between (a) a flow rate of a gas when the substrate is processed with various changes in the flow rates of specific types of gases (gas A and gas B) and (b) the evaluation values obtained based on the surface images observed in the processes. Specifically, FIG. 10 illustrates the relationship between the parameter (flow rates of the gas A) when substrates are processed according to a plurality of recipes in which the flow rates of the gas A are varied, and the evaluation values obtained based on the surface images obtained in the processes, and the relationship between the parameter (flow rates of the gas B) when substrates are processed according to a plurality of recipes in which the flow rates of the gas B are varied, and the evaluation values obtained based on the surface images obtained in the processes. The flow rate of the gas may be a setting value of the process recipe, or may be an actual measurement value measured by a flow rate sensor provided in the substrate processing apparatus 100.

FIG. 10 illustrates an example of a table in which the relationship between the flow rates of specific types of gases (gas A and gas B) and the evaluation values is stored. Alternatively, the parameters to be registered in the table may be any parameters set by a process recipe, such as a sum of the flow rates of all the gases, a substrate temperature, or a voltage and a current applied when plasma is generated in the processing chamber.

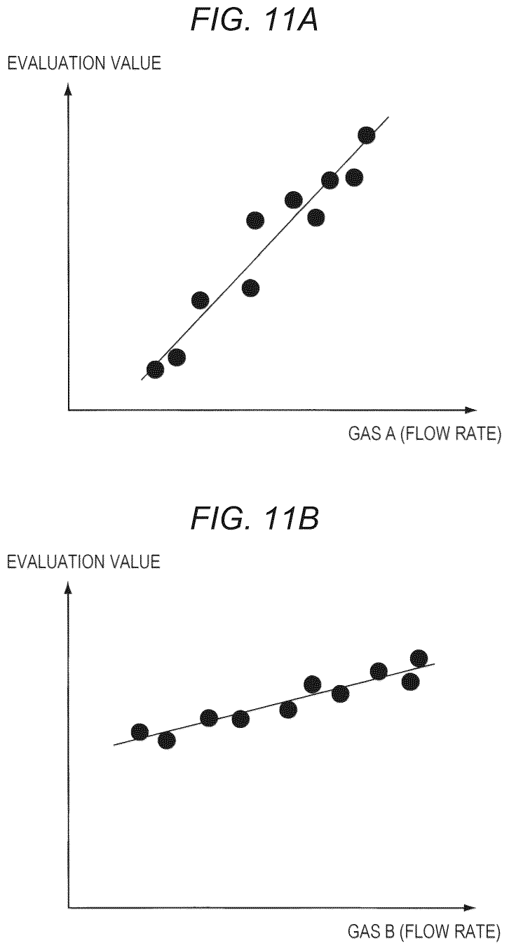

The controller 301 of the evaluation apparatus 300 derives the correlations between the parameter included in the process recipes and the evaluation values. FIGS. 11A and 11B are graphs illustrating correlations between the parameters included in the process recipe and the evaluation values. FIG. 11A illustrates a correlation between the flow rate of a specific type of gas (gas A) and the evaluation value, and FIG. 11B illustrates a correlation between the flow rate of another type of gas (gas B) and the evaluation value. In each graph, a horizontal axis represents the flow rate of the gas, and a vertical axis represents the evaluation value. Based on these graphs, it can be understood that when the flow rate of the gas A is changed, the evaluation value varies considerably, and the flow rate of the gas A has a large influence on the structural uniformity of the substrate. Existing methods such as linear regression, ridge regression, regression tree, random forest, and neural network are used to derive the correlation.

Based on the correlation between the parameter included in the process recipes and the evaluation values, the evaluation apparatus 300 can optimize the process recipe used when the substrate is processed. For example, when the correlation illustrated in FIGS. 11A and 11B is obtained, the evaluation value changes considerably when the flow rate of the gas A is changed, and thus the structural uniformity of the substrate can be improved by adjusting the setting value of the flow rate of the gas A in the process recipe.

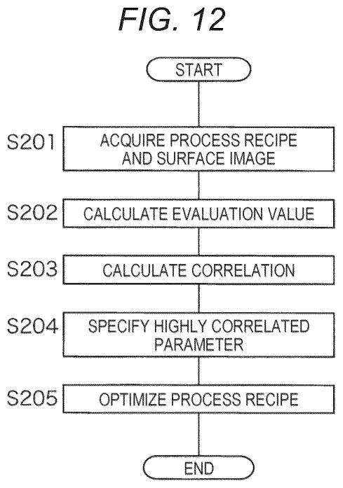

FIG. 12 is a flowchart illustrating a procedure for optimizing a process recipe. The controller 301 of the evaluation apparatus 300 acquires a process recipe used when the substrate is processed, and a surface image obtained by observing the substrate (step S201).

The controller 301 calculates an evaluation value based on the observed image (step S202). The procedure for calculating the evaluation value is the same as that in the above discussion, and an evaluation value for quantitatively evaluating the structural uniformity of the substrate is calculated by comparing the features extracted from the surface image of the substrate as the evaluation target with the features extracted from the non-defective image.

The controller 301 calculates the correlation between the evaluation value calculated in step S202 and the parameters included in the process recipe (step S203), and specifies the parameter that has a high correlation with the evaluation value (step S204).

The controller 301 adjusts the specified parameters to optimize the process recipe so as to improve the structural uniformity of the substrate (step S205). The controller 301 optimizes the process recipe by rewriting the value of the parameter in the process recipe. The operator may determine whether a desired result is obtained by performing substrate processing by the substrate processing apparatus 100 according to an optimized process recipe and performing re-evaluation using the evaluation apparatus 300.

The flowchart of FIG. 12 describes a procedure of acquiring a plurality of types of process recipes, calculating the correlations between parameters included in the acquired process recipes and evaluation values calculated for substrates processed according to the process recipes, and optimizing the process recipe based on the calculated correlations. Alternatively, the controller 301 may execute the processing after step S204, based on the correlations (correlations between the parameters included in the process recipe and the evaluation values for the substrate) acquired in advance.

As described above, the correlations between the evaluation values calculated based on the surface image and the parameters included in the process parameters can be calculated, and the process recipe can be optimized so as to improve the structural uniformity of the substrate.

The embodiments disclosed herein are exemplary in all respects and are required to be considered to be not restrictive embodiments. The scope of the present invention is indicated by the scope of the aspects, not the meaning described above, and is intended to include meanings equivalent to the scope of the aspects and all changes within the scope.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

1. An evaluation method, comprising:
acquiring a surface image of a material as an evaluation target;
extracting a first feature from the surface image;
reading, from a memory, a plurality of second features extracted from surface images of a plurality of materials having structural uniformity;
calculating a distance in a feature space between the first feature and a second feature of the plurality of second features;
calculating, based on the distance, an evaluation value for quantitatively evaluating a structural uniformity of the material as the evaluation target; and
outputting the evaluation value.

2. The evaluation method according to claim 1, wherein further comprising:
generating an evaluation image having the structural uniformity based on the distance; and
displaying the evaluation image together with the evaluation value.

3. The evaluation method according to claim 1, further comprising:
acquiring a plurality of types of recipes for processing the material as the evaluation target;
calculating correlations between parameters included in the recipes and evaluation values calculated for materials processed according to the recipes; and
optimizing a recipe for processing the material based on the calculated correlations.

4. The evaluation method according to claim 1, further comprising:
optimizing a recipe, for processing the material, based on correlations between parameters included in a plurality of types of recipes for processing the material as the evaluation target and evaluation values calculated for materials processed according to the recipes.

5. The evaluation method according to claim 3, further comprising:
generating an evaluation image for each recipe; and
displaying the evaluation images in a descending order of the evaluation values.

6. The evaluation method according to claim 4, further comprising:
generating an evaluation image for each recipe; and
displaying the evaluation images in a descending order of the evaluation values.

7. The evaluation method according to claim 1, wherein the extracting the first feature and extraction of the second feature are performed using a trained learning model including a feature extraction layer.

8. The evaluation method according to claim 1, wherein the structural uniformity includes at least one of uniformity of a patterned structure formed on a surface of the material, roundness of a plurality of holes formed in the material, uniformity of a surface state accompanying cleaning of the material, and a degree of deterioration of a surface accompanying processing of the material.

9. The evaluation method according to claim 1, wherein the material is a substrate to be processed by a substrate processing apparatus.

10. The evaluation method according to claim 1, further comprising enlarging the surface image before the extracting the first feature.

11. The evaluation method according to claim 10, further comprising masking a portion of the surface image before the extracting the first feature.

12. The evaluation method according to claim 1, further comprising masking a portion of the surface image before the extracting the first feature.

13. The evaluation method according to claim 1, further comprising reducing the surface image before the extracting the first feature.

14. The evaluation method according to claim 13, further comprising masking a portion of the surface image before the extracting the first feature.

15. The evaluation method according to claim 1, further comprising storing the first feature in the memory.

16. The evaluation method according to claim 1, further comprising releasing the mask and restoring the surface image to its original size.

17. The evaluation method according to claim 1, further comprising generating an evaluation image indicating an evaluation of the structural uniformity for the material as the evaluation target.

18. The evaluation method according to claim 17, further comprising outputting the evaluation image.

19. An evaluation apparatus, comprising:
a memory which stores a plurality of features extracted from surface images of a plurality of materials having structural uniformity; and
processing circuitry configured to:
acquire a surface image of a material as an evaluation target;
extract a first feature from the surface image;
read the plurality of features from the memory;
calculate a distance in a feature space between the first feature and a second feature of the plurality of features;
calculate, based on the distance, an evaluation value for quantitatively evaluating a structural uniformity of the material as the evaluation target; and
output the evaluation value.

20. A non-transitory computer readable medium storing computer executable instructions which, when executed by a computer, cause the computer to execute a process comprising:
acquiring a surface image of a material as an evaluation target;
extracting a first feature from the surface image;
reading, from a memory, a plurality of second features extracted from surface images of a plurality of materials having structural uniformity;
calculating a distance in a feature space between the first feature and a second feature of the plurality of second features;
calculating, based on the distance, an evaluation value for quantitatively evaluating a structural uniformity of the material as the evaluation target; and
outputting the evaluation value.
